(19) United States
(12) Patent Application Publication
(10) Pub. No.: US 2026/0075850 A1
(43) Pub. Date: Mar. 12, 2026

(54) Decoupling Capacitors in Semiconductor Devices and Methods of Forming the Same

(71) Applicant: Texas Instruments Incorporated, Dallas, TX (US)

(72) Inventors: Chinna Veerappan V, KRISHNAGIRI (IN); Shashi Thakur, BENGALURU (IN)

(21) Appl. No.: 19/303,685

(22) Filed: Aug. 19, 2025

(30) Foreign Application Priority Data
Sep. 6, 2024 (IN) 202441067471

(51) Int. Cl. H10D 1/66; H01L 21/762; H10D 1/00; H10D 62/10

(52) U.S. Cl. CPC H10D 1/665; H10D 1/047; H10D 62/126; H10W 10/014; H10W 10/17

(57) ABSTRACT

A semiconductor device is disclosed herein. The semiconductor device includes a buried semiconductor layer disposed over a substrate and having a first conductivity type, an epitaxial layer disposed over the buried semiconductor layer and having an opposite second conductivity type, a deep trench isolation structure extending through the epitaxial layer, the buried semiconductor layer, and into the substrate, and a capacitor disposed over the substrate The capacitor interfaces with the deep trench isolation structure and is electrically coupled to the buried semiconductor layer.

### CROSS-REFERENCE TO RELATED APPLICATIONS

This application claims priority to India provisional patent application No. 202441067471 filed September 6, 2024, which is hereby incorporated by reference in its entirety.

### FIELD

The present disclosure generally relates integrated semiconductor devices, and more particularly, to integrated capacitors.

### BACKGROUND

Decoupling capacitors are used in semiconductor devices, including integrated circuits, to prevent electrical energy transfer, decouple, one part of the semiconductor device from another. Decoupling capacitors may help to stabilize the power supply and reduce electrical noise in the semiconductor device. Generally, decoupling capacitors are placed near the power supply. In some semiconductor devices, two unique power supplies may be used. Decoupling capacitors may be used to isolate the two power supplies.

### SUMMARY

A semiconductor device is disclosed herein. The semiconductor device includes a buried semiconductor layer disposed over a substrate and having a first conductivity type, an epitaxial layer disposed over the buried semiconductor layer and having an opposite second conductivity type, a trench isolation structure extending through the epitaxial layer, the buried semiconductor layer, and into the substrate, and a capacitor disposed over the substrate The capacitor interfaces with the trench isolation structure and is conductively coupled to the buried semiconductor layer.

Also disclosed herein is an electronic device including a buried semiconductor layer having a first conductivity type disposed over a semiconductor substrate, a semiconductor layer having an opposite second conductivity type disposed over the buried semiconductor layer, and a trench extending through the semiconductor layer to at least the buried semiconductor layer. The electronic device further includes a doped region disposed within the semiconductor layer and along a sidewall of the trench. The doped region extends to at least the buried semiconductor layer and has the first conductivity type. The electronic device further includes a capacitor. The capacitor includes a doped well forming a plate of the capacitor. The doped well is disposed within the semiconductor layer and has the first conductivity type. The doped well interfaces with the trench and the doped region and is conductively coupled to the buried semiconductor layer by the doped region.

Also disclosed herein is a method of forming an integrated circuit. The method includes forming a trench through a first semiconductor layer that has a first conductivity type to a second semiconductor layer that has an opposite second conductivity type. The method further includes forming a doped region having the second conductivity type within the first semiconductor layer so that the doped region intersects a sidewall of the trench. The method further includes and forming a conductive layer over the doped region so that the doped region forms a first plate of a capacitor and the conductive layer forms a second plate of the capacitor.

The foregoing features and elements may be combined in any combination, without exclusivity, unless expressly indicated herein otherwise. These features and elements as well as the operation of the disclosed examples will become more apparent in light of the following description and accompanying drawings.

### BRIEF DESCRIPTION OF THE DRAWINGS

Reference will now be made to the accompanying drawings, which are not necessarily drawn to scale. While the drawings illustrate various examples employing the principles described herein, the drawings do not limit the scope of the claims.

FIGS. 1A, 1B, and 1C, illustrate views of a decoupling capacitor of an integrated circuit, in accordance with various examples.

FIGS. 2A and 2B illustrate views of a decoupling capacitor of an integrated circuit, in accordance with various examples.

FIGS. 3A and 3B illustrate views of a decoupling capacitor of an integrated circuit, in accordance with various examples.

FIG. 4 illustrates a flowchart for a method of forming a decoupling capacitor in accordance with the devices of FIGS. 1A-1C, FIGS. 2A and 2B, and FIGS. 3A and 3B, and the various examples associated therewith.

### DETAILED DESCRIPTION

The following detailed description is presented for purposes of illustration and not of limitation. Benefits, advantages, and/or solutions to problems may be described with reference to various examples. The detailed description makes use of the various examples and refers to the accompanying drawings which illustrate the various examples described herein. The drawings, descriptions, and examples are described in sufficient detail to practice the disclosure. It is understood that connecting lines shown in the various drawings are intended to represent example functional relationships and/or physical couplings between various elements, but that other relationships and/or couplings are possible while remaining within the scope of the present disclosure. It will further be appreciated that the various drawings may not be drawn to scale in order to simplify and clarify the detailed description herein. Furthermore, it is understood that the descriptions and examples contained herein may permit the practice other examples using logical, chemical, and/or mechanical changes without departing from the spirit and scope of this disclosure. For example, the steps recited in method and process descriptions may be executed in a different order, additional process steps may be added, and/or process steps may be removed while remaining within the scope of the present disclosure.

Any reference to singular items and/or examples includes plural items and/or examples and any reference to more than one item and/or example may include a singular item and/or example. Similarly, references to “a”, “an”, or “the” may include one or more of the referenced items, unless stated otherwise. Any reference to connected, coupled, fixed, attached, or the similar words and/or phrases may include partial, full, temporary, removable, permanent, or the other connection options. Any reference to contact, or similar phrase, may include minimal contact or reduced contact. All ranges used herein may include both the upper and lower values of the ranges, including ratio limits, that are disclosed herein. Stated values may include at least the variation that is expected within the field in which the present disclosure is practiced and as would be understood and accepted to include values that are within 10% of a stated value. Similarly, the use of “approximately”, “about”, “substantially” or other similar term represents an amount that is close to the stated value and that may still achieve the stated, or desired, result and/or perform the stated, or desired, function and may refer to an amount that is within 10% of the stated value.

The accompanying drawings, and detailed description of the drawings, include reference numerals that may be repeated across multiple examples. The repetition of reference numerals is intended for simplicity and clarity of description and is not intended to form or dictate a relationship between different examples described herein. The examples and descriptions provided herein are intended to be illustrative and not limiting beyond the scope of the claims. The use of terms such as “on” and “over” may indicate that a first feature is formed directly contacting a second feature or may indicate a relationship of the first feature and the second feature without direct contact between the two, such as additional features being formed between the two. For example, “on” may be used to indicate direct contact between the two and “over” may be used to indicate either direct contact or being spaced apart by one or more intervening layers.

Spatially relative terms such as, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of discussion herein and are not intended to limit the orientation of the various components, systems, apparatuses, devices, or other features. It is therefore understood and appreciated that the use of the spatially relative terms to practice this disclosure in different orientations remains within the scope of the present disclosure.

Decoupling capacitors may be used in integrated circuit devices, including those with more than one power supply. In various examples, one or more decoupling capacitors may use up to about 15% to about 20% of the die size for a given integrated circuit. Baseline processes may form decoupling capacitors that are near to, but not interfacing with, a scribe region (e.g., scribe seal) of the integrated circuit device. In other words, there is typically a gap (e.g., laterally spaced apart) between the scribe region and the decoupling capacitor. Additionally, decoupling capacitors formed using baseline processes are designed to be about 5 to about 6 times wider than they are long. That is, decoupling capacitors extend about 5 to about 6 times more into (e.g., along the width) the die area (e.g., active circuitry region) than along an edge (e.g., along the length) of the scribe region. As such, baseline processes design decoupling capacitors having a length to width ratio of about 1:5 to about 1:6. Furthermore, baseline decoupling capacitors may include multiple fingers (e.g., connections, contacts, etc.), to provide a connection between a bottom plate and a substrate potential that extends through breaks or openings in a top plate of the decoupling capacitor (providing a low equivalent series resistance connection), thereby using significant die space for a given capacitance.

Disclosed herein are decoupling capacitors that use less die space than baseline decoupling capacitors without negatively affecting the equivalent series resistance (ESR) of the decoupling capacitor, as compared to baseline decoupling capacitors. In various examples, decoupling capacitors consistent with the disclosure may be formed adjacent to and interfacing with a scribe structure of the integrated circuit. In some examples, the decoupling capacitor may be partially formed over a portion of an isolation structure (e.g., deep trench isolation structure) within the scribe region. In various examples, interfacing with the scribe region, and more specifically, with a buried layer pf the scribe region provides a direct connection from the bottom plate to the substrate potential through the buried layer. The direct connection removes the use of fingers, or multiple contacts, to the bottom plate through openings (or breaks) in the top plate, thereby reducing the die area consumed by the decoupling capacitor. Furthermore, the decoupling capacitor described herein may extend along the scribe region by a length that is at least 10 times a width by which the capacitor extends laterally away from the scribe region into the die area. In various examples, the length to width ratio (sometimes referred to as the “aspect ratio”) may be in a range from about 20:1 to about 60:1, and in some cases about 35:1 to about 45:1. Finally, the architecture of the decoupling capacitor disclosed herein ensures good electrical connection for both the bottom plate and the top plate (including between the bottom plate and the buried layer) and good ESR values without using additional verification checks during the manufacturing process. While such examples may be expected to provide the described benefits, no particular result is a requirement of the present invention unless explicitly recited in a particular claim.

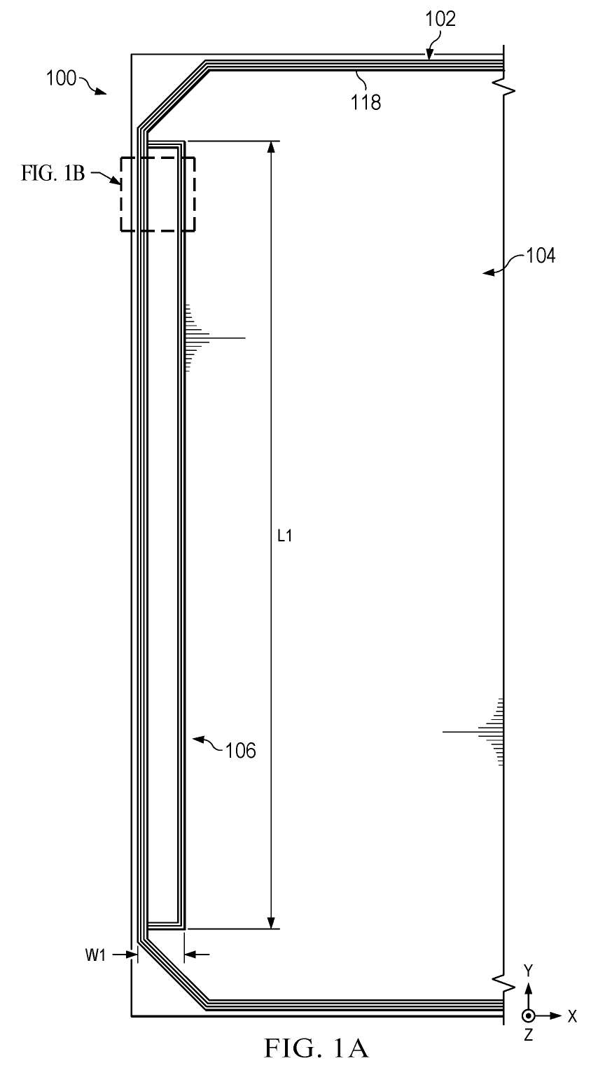

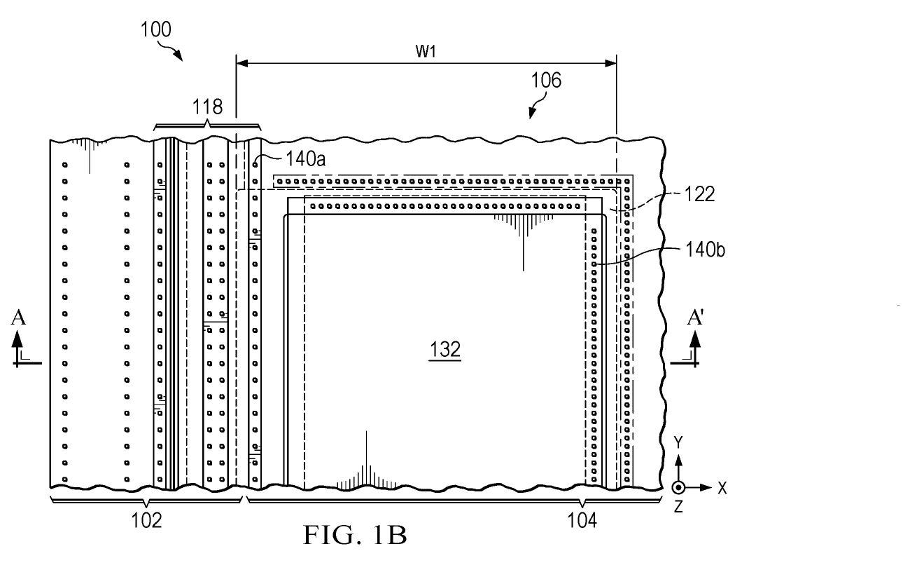

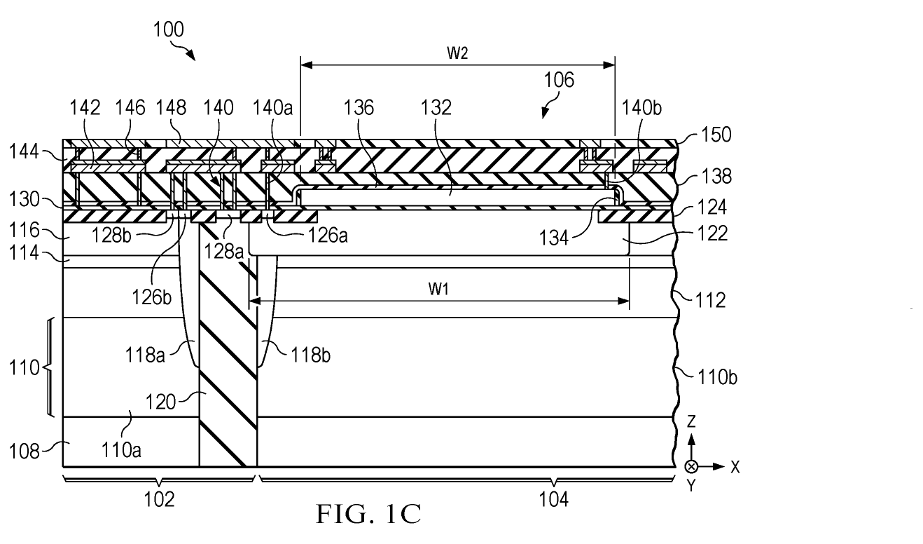

Referring now to FIGS. 1A-1C, top-down and cross section views of an integrated circuit 100 are illustrated according to various aspects of the present disclosure. FIG. 1A is a top-down view of integrated circuit 100 including a scribe region 102, a die area 104, and a decoupling capacitor 106 extending along the scribe region 102. FIG. 1B is a close-up, top-down view of a portion of integrated circuit 100 including a portion of decoupling capacitor 106. FIG. 1C is a diagrammatic cross-sectional view of integrated circuit including decoupling capacitor 106. In various examples, integrated circuit 100 may be a single circuit or may be part of a larger circuit. For example, integrated circuit 100 may be part of a larger integrated circuit that uses two unique power supplies. Decoupling capacitor 106 may provide electrical isolation between the two unique power supplies to reduce electric noise.

Referring to FIG. 1A, a portion of integrated circuit 100 is shown, including scribe region 102 that separates integrated circuit 100, including a first power supply, from another integrated circuit having a second, unique power supply. As shown in FIG. 1A, scribe region 102 (e.g., scribe seal) extends around an outer perimeter of integrated circuit 100 including surrounding die area 104. Scribe region 102 abuts a scribe street (e.g., space, not shown) between adjacent dies on a semiconductor wafer (e.g., semiconductor substrate). This scribe street may be used for separating the die areas during a semiconductor wafer dicing process. Die area 104 refers to the area on the semiconductor wafer that contains components of an integrated circuit such as integrated circuit 100. In various examples, die area 104 may include any number and/or type of semiconductor components (e.g., functional and non-functional components) forming an integrated circuit such as transistors, resistors, capacitors, interconnect structures, logic circuitry, analog circuitry, memory, or other like components. For simplicity and clarity, integrated circuit 100 is shown with one die area surrounded by scribe region 102. However, the present disclosure is not limited to any number of integrated circuits, scribe regions and/or die areas.

As shown in FIGS. 1A and 1C, scribe region 102 includes portions of a deep well 118 that extend around the outer perimeter (e.g., within scribe region 102) of integrated circuit 100. In various examples, deep well 118 and scribe region 102 may be concentric. In various examples, deep well 118 may be tied to the substrate potential of integrated circuit 100, as described further below.

Decoupling capacitor 106 is disposed along an edge of scribe region 102 including over deep well 118. Decoupling capacitor 106 has a first length L₁ (e.g., along an edge of scribe region 102 (e.g., along the y-axis)) and a first width W₁ (e.g., along the x-axis into die area 104), and an aspect ratio L₁/W₁. As shown, first length L₁ is substantially greater than first width W₁. In various examples, the aspect ratio may be in a range from about 20:1 to about 60:1, and in some cases about 35:1 to about 45:1. The relatively large length to width ratio of decoupling capacitor 106 combined with being disposed over deep well 118 provides a good connection to the substrate potential (e.g., ground, 0 V) through underlying layers (e.g., first buried layer 110 described below), reduces the overall die size, and ensures a good equivalent series resistance (ESR) of decoupling capacitor 106.

Referring now to FIG. 1B, a magnified top down view of a portion of decoupling capacitor 106 as marked in FIG. 1A is shown extending along an edge of scribe region 102, including over deep well 118. Additionally, bottom plate contacts 140a, top plate contacts 140b and top plate 132 are shown. Bottom plate contacts 140a and top plate contacts 140b are disposed over laterally spaced apart sides of decoupling capacitor 106. In various other examples, the orientation and arrangement of bottom plate contacts 140a and top plate contacts 140b may differ from those illustrated. As will be described in further detail below, a bottom plate of decoupling capacitor 106 is conductively coupled to bottom plate contacts 140a and a top plate of decoupling capacitor 106 is conductively coupled to top plate contacts 140b (e.g., a voltage potential, VDD, etc.).

Referring now to FIG. 1C, a cross-section of integrated circuit 100 along the line A-A’ of FIG. 1B is shown. Integrated circuit 100 includes a semiconductor substrate 108, first buried layer 110, a second semiconductor layer 112, a second buried layer 114, a doped semiconductor layer 116, deep well 118, a deep isolation structure 120, a shallow well 122, shallow isolation structures 124, contact regions 126, contact regions 128, a dielectric layer 130, a top plate 132, sidewall spacers 134, a dielectric liner 136, a first interlayer dielectric (ILD) layer 138, contacts 140, a first metal layer 142, a second ILD layer 144, vias 146, a second metal layer 148, and a third ILD layer 150.

Semiconductor substrate 108 may include a bulk semiconductor substrate, a semiconductor-on-insulator (SOI) substrate, or any other appropriate substrate. For example, the semiconductor substrate 108 may be or include a bulk silicon wafer. In various examples, semiconductor substrate 108 may include a dielectric material, an epitaxially grown material, and/or any other any material and/or layer on which the process described herein may be performed. For example, semiconductor substrate 108 may include one or more epitaxially grown layers disposed on a semiconductor substrate (e.g., silicon substrate).

First buried layer 110 (e.g., first buried semiconductor layer) is disposed over semiconductor substrate 108 and has a first conductivity type. In various examples, at least a portion of first buried layer 110 may be part of scribe region 102. For example, first buried layer 110 may include a first portion 110a and a second portion 110b with first portion 110a being part of scribe region 102 and second portion 110b extending within die area 104. Furthermore, first buried layer 110 has a first voltage potential. In various examples, the first voltage potential may be a device voltage potential (e.g., ground). In various examples, first buried layer 110 may include one or more semiconductor layers such as silicon (Si), germanium (Ge), or silicon germanium (SiGe), the like, or a combination thereof. In various examples, the dopant used may be one or more n-type dopants or one or more p-type dopants. The n-type dopants, in various examples, may be arsenic (Ar), phosphorous (P), antimony (Sb), the like, or a combination thereof. In various examples, the p-type dopant may be boron (B), indium (In), the like, or a combination thereof. In various examples, first buried layer 110 may be an n-type buried semiconductor layer.

Semiconductor layer 112 (e.g., an epitaxial layer) is disposed over first buried layer 110. In various examples, semiconductor layer 112 may include one or more semiconductor layers. In various examples, semiconductor layer 112 may have a second conductivity type that is opposite the first conductivity type. For example, when first buried layer 110 is doped with one or more n-type dopants, semiconductor layer 112 may be doped with one or more p-type dopants. In another example, when first buried layer 110 is doped with one or more p-type dopants, semiconductor layer 112 may be doped with one or more n-type dopants. In various examples, semiconductor layer 112 may be epitaxially grown. In various examples, semiconductor layer 112 may also be referred to as doped region. In various examples, semiconductor layer 112 may be a p-type semiconductor layer.

Second buried layer 114 (e.g., second buried semiconductor layer) is disposed over semiconductor layer 112. Second buried layer 114 may include one or more semiconductor layers. In various examples, second buried layer 114 may be epitaxially grown. In various examples, second buried layer 114 may have the second conductivity type. For example, when semiconductor layer 112 is doped with one or more p-type dopants, second buried layer 114 may be doped with one or more p-type dopants. In various examples, the dopant concentration of semiconductor layer 112 may be greater than the dopant concentration of second buried layer. In various examples, second buried layer 114 may also be referred to as a doped region.

Doped semiconductor layer 116 is disposed over second buried layer 114. In various examples, doped semiconductor layer 116 may include one or more semiconductor layers. In various examples, doped semiconductor layer 116 may have the second conductivity type. In various examples, doped semiconductor layer 116 may be doped with a dopant type that is the same as the dopant type used in second buried layer 114. For example, when second buried layer 114 is doped with one or more p-type dopants, doped semiconductor layer 116 may be doped with one or more p-type dopants. In various examples, doped semiconductor layer 116 may be epitaxially grown. In various examples, doped semiconductor layer 116 may have a higher concentration of dopant than second buried layer 114.

Deep well 118 (including first portion 118a and second portion 118b) extends through first buried layer 110, semiconductor layer 112, second buried layer 114, and doped semiconductor layer 116. As shown, in some examples, deep well 118 terminates within first buried layer 110 such that deep well 118 does not extend completely through first buried layer 110. In various examples, deep well 118 has the first conductivity type and may be or include similar semiconductor materials as first buried layer 110, semiconductor layer 112, second buried layer 114, and/or doped semiconductor layer 116. In various examples, the dopant used may be one or more n-type dopants or one or more p-type dopants. In various examples, deep well 118 may be referred to as a doped region.

Deep isolation structure 120 (e.g., deep trench isolation structure, trench) extends through deep well 118, first buried layer 110 (including first portion 110a and second portion 110b), and may further extend into semiconductor substrate 108 as shown. In various examples, first portion 110a and second portion 110b may be electrically isolated and may each be at different electrical potentials. In various examples, deep isolation structure 120 may be a deep trench isolation structure, and as such is formed within a trench extending through the various semiconductor layers. Deep isolation structure 120 electrically isolates (or conductively isolates) decoupling capacitor 106 from scribe region 102. In various examples, deep isolation structure 120 may be disposed within scribe region 102. In various examples, deep isolation structure 120 may extend around an outer perimeter of integrated circuit 100. In various examples, as shown in FIG. 1C, a first portion 118a of deep well 118 may interface with a first sidewall of deep isolation structure 120 and a second portion 118b of deep well 118 may interface with an opposing second sidewall of deep isolation structure 120.

In various examples, deep isolation structure 120 may include a dielectric trench sidewall liner and a trench fill material. The trench sidewall liner may include one or more dielectric (insulating) materials such as silicon oxide, silicon nitride, silicon oxynitride, the like, and/or a combination thereof. The fill material may include polycrystalline silicon (sometimes referred to as polysilicon or poly), doped polysilicon, amorphous silicon, dielectric material, one or more conductive metals, the like, and/or a combination thereof. Deep isolation structure 120 may be formed using various processes. For example, a trench may be formed through deep well 118, first buried layer 110, and into semiconductor substrate 108. The deep trench oxide may then be formed along exposed sidewall surfaces of the trench, and the deep trench fill material may be used to fill the remaining space in the trench between the deep trench oxide lined sidewall surfaces.

As described below, decoupling capacitor 106 may include shallow well 122 (sometimes referred to as shallow doped well or doped region) as a bottom plate, top plate 132 as a top plate and portions of dielectric layer 130 therebetween as an insulating material of the capacitor. In that regard, shallow well 122 forms a bottom plate of decoupling capacitor 106 and has first width W₁ and first length L₁ (shown in FIG. 1A). Shallow well 122 is disposed in doped semiconductor layer 116 and extends over portions of second buried layer 114, deep well 118 (e.g., second portion 118b), and deep isolation structure 120. In various examples, as shown, shallow well 122 may interface with (e.g., touch, physically contact, abut, or the like) and form an ohmic connection to deep well 118 and deep isolation structure 120. Additionally, as shown in FIG. 1C, in some examples, shallow well 122 may extend within scribe region 102 and be positioned (or formed) over a portion of deep isolation structure 120. Moreover, in various examples, shallow well 122 may be conductively coupled to first buried layer 110 through deep well 118. The direct connection of shallow well 122 to deep well 118 along first length L₁ of decoupling capacitor 106 provides an electrical connection for decoupling capacitor 106 to a first voltage line (e.g., ground, substrate potential) through first buried layer 110. The electrical connection of shallow well 122 (e.g., bottom plate) to the first voltage line reduces the die space (e.g., within die area 104) used by decoupling capacitor 106 by removing the multiple fingers (e.g., contacts) used in baseline processes to provide a voltage connection to the bottom plate through top plate 132. In other words, unlike some baseline solutions, decoupling capacitor 106 has a continuous top plate (e.g., top plate 132) that lacks fingers (or interdigitations) that otherwise would require more die area. As such, decoupling capacitor 106 occupies less space (e.g., die area) than baseline processes.

In various examples, shallow well 122 has the first conductivity type and may be or include similar semiconductor materials as deep well 118. In various examples, the dopant used may be one or more n-type dopants or one or more p-type dopants. Accordingly, in some examples shallow well 122 may be doped using n-type dopants (e.g., an n-type doped well feature) when deep well 118 is doped using n-type dopants, and in such examples may be referred to as an n-type well. Similarly, shallow well 122 may be doped using p-type dopants when deep well 118 is doped using p-type dopants, and in such examples may be referred to as a p-type well.

In various examples, shallow well 122 may be formed after forming deep well 118 and deep isolation structure 120. In various examples, one or more etching processes may be used to remove portions of deep well 118 and deep isolation structure 120. Shallow well 122 may then be formed over second buried layer 114 and the remaining portions of deep well 118 and deep isolation structure 120. In various examples, process parameters may be adjusted to form shallow well 122 over deep well 118 and deep isolation structure 120. In various examples, one or more planarization processes may be performed to planarize a top surface of shallow well 122. In various examples, the one or more planarization processes may include etching, chemical mechanical polishing (CMP), the like, or a combination thereof.

Shallow isolation structures 124 are disposed over doped semiconductor layer 116, deep well 118, deep isolation structure 120, and shallow well 122. Shallow isolation structures 124 provide electrical isolation between decoupling capacitor 106 and other portions of integrated circuit 100. In various examples, shallow isolation structures 124 may include shallow trench isolation (STI) structures. In various examples, shallow isolation structures 124 may include dielectric materials providing electrical isolation such a silicon oxide, silicon nitride, silicon oxynitride, the like, and/or a combination thereof.

Contact regions 126a, 126b are disposed over deep well 118 and shallow well 122. In various examples, the contact regions 126a, 126b may interface with (e.g., touch, physically contact, abut, or the like) deep well 118 and/or shallow well 122. Contact regions 126a, 126b have the first conductivity type. In various examples, the dopant used may be one or more n-type dopants or one or more p-type dopants. In various examples, contact regions 126a, 126b may have a higher concentration of the dopants used than deep well 118 and/or shallow well 122. In various examples, contact region 126a may provide an electrical connection to shallow well 122 (e.g., the bottom plate) of decoupling capacitor 106. In various other examples, contact regions 126a, 126b may be discontinuous with each other such that contact regions 126a, 126b are not one continuous region. In other examples, contact regions 126a, 126b may be one continuous region. In various examples, contact region 126a may be surrounded by shallow well 122. In various examples, contact region 126a has a higher conductivity than shallow well 122.

Contact region 128a is disposed over deep isolation structure 120 and contact region 128b is disposed over doped semiconductor layer 116. In various examples, contact region 128a provides an ohmic connection to deep isolation structure 120, and contact region 128b provides an ohmic connection to doped semiconductor layer 116. Contact region 128a has the same conductivity type as the fill material of the deep isolation structure 120 when the fill material is a doped semiconductor, e.g. p-type polysilicon, while contact region 128b has the same conductivity type as the doped semiconductor layer 116, e.g. p-type. In some other examples, the fill material and/or the doped semiconductor layer 116 may be n-type dopants. In various examples, contact region 128a has a greater concentration of the dopants used than does deep isolation structure 120, and contact region 128b has a greater concentration of the dopants used than does doped semiconductor layer 116. Contact region 128a may be omitted in examples in which the deep isolation structure includes metal fill.

Dielectric layer 130 is disposed over shallow well 122, and may be formed during gate oxide formation related to various transistors in the die area 104. The dielectric layer 130 is shown extending over the shallow isolation structures 124, contact regions 126, and contact regions 128, while in some examples the dielectric layer 130 is removed as a consequence of forming sidewall spacers 134. As described above, the portion of dielectric layer 130 disposed between shallow well 122 (e.g., bottom plate) and top plate 132 (e.g., top plate) provides a capacitor dielectric for decoupling capacitor 106. The use of the term silicon oxide throughout this disclosure includes materials such as silicon monoxide (SiO) and/or silicon dioxide (SiO₂) and/or a non-stoichiometric mixture of the two. In some examples the dielectric layer 130 is a thermally grown silicon oxide layer. some other examples, dielectric layer 130 may include local oxidation of silicon (LOCOS) oxide. In various examples, dielectric layer 130 may include silicon oxide, silicon nitride, silicon oxynitride, a silicon oxide-based material (such as a phosphosilicate glass (PSG) or a tetraethyl orthosilicate (TEOS) oxide), polytetrafluoroethylene, high-k dielectric layers, any other dielectric material, or any combination thereof.

Top plate 132 is disposed over dielectric layer 130 including over a portion of shallow well 122 (e.g., bottom plate). As described above, top plate 132 forms the top plate of decoupling capacitor 106. In some examples, as shown, top plate 132 has a second width W₂ that is less than first width W₁ of shallow well 122. The first width W₁ may define the die space used by decoupling capacitor 106, and the second width W₂ of top plate 132 may define the effective width (or capacitive width) of decoupling capacitor 106. Top plate 132 as shown in FIG. 1C is a continuous material layer because there are no openings in top plate 132 to provide electrical connections (e.g., contacts) to shallow well 122. Furthermore, top plate 132 is shown laterally spaced apart from deep isolation structure 120. In various examples, top plate 132 may be spaced apart from deep isolation structure 120 and laterally with respect to a top surface of shallow well 122. Such examples reduce the area occupied by decoupling capacitor 106 within a die area (e.g., die area 104) without negatively affecting the ESR of decoupling capacitor 106. Additionally, the absence of breaks in top plate 132 used by baseline processes reduces capacitive interference caused by the breaks.

In various examples, top plate 132 may include polycrystalline silicon. For example, top plate 132 may be a polysilicon structure that includes at least one polysilicon layer. In other examples, top plate 132 may include other metals and metal alloys. For example, top plate 132 may include metal alloys such as titanium nitride (TiN), tantalum nitride (TaN), and/or a combination thereof. In other examples, top plate 132 may include copper (Cu), tungsten (W), and/or aluminum (Al). In various examples, top plate 132 has a different material composition than shallow well 122. For example, shallow well 122 may be a doped region formed in a semiconductor layer (e.g., silicon and/or germanium epitaxial layer) while top plate 132 includes polysilicon (or metal and/or metal alloys described above). In various examples, top plate 132 may also be referred to as a conductive layer.

Sidewall spacers 134 are disposed along sidewalls of top plate 132. Sidewall spacers 134 (sometimes referred to as dielectric spacers) may include one or more layers of an oxide material (e.g., silicon oxide), a nitride material (e.g., silicon nitride and/or silicon oxynitride), or combinations thereof. Sidewall spacers 134 may be formed using any known process, such as for example, chemical vapor deposition (CVD), and/or physical vapor deposition (PVD), among others. In various examples, a dielectric material may be formed over integrated circuit 100 which is subsequently etched to form sidewall spacers 134.

Dielectric liner 136 is disposed over top plate 132, sidewall spacers 134, and dielectric layer 130. Dielectric liner 136 may include one or more layers of a dielectric material including an oxide and/or nitride material such as silicon oxide and/or silicon nitride. Dielectric liner 136 may be used as silicide blocking layer related to the formation of electrical components in the die area 104, and may be removed over the contact regions 126a, 126b, 128a, 128b to allow formation of silicide layers (not shown) over these regions.

First interlayer dielectric (ILD) layer 138 is disposed over dielectric liner 136. First ILD layer 138 may be a single dielectric layer or may include multiple dielectric layers of a same dielectric material or different dielectric materials. In various examples, first ILD layer 138 may include silicon nitride, a silicon oxide-based material (such as a phosphosilicate glass (PSG), borophosphosilicate glass (BPSG), or a tetraethyl orthosilicate (TEOS) oxide), polytetrafluoroethylene, or the like.

Contacts 140 include bottom plate contact 140a and top plate contact 140b. Bottom plate contact 140a provides a conductive connection to shallow well 122 (e.g., the bottom plate) and top plate contact 140b provides a conductive connection to the top plate 132. In various examples, the other contacts 140 provide other electrical and structural connections at the same layer as contacts 140a and 140b. In that regard, contacts 140 are disposed through first ILD layer 138, dielectric liner 136, and/or dielectric layer 130 and land on (and conductively contact) contact regions 126 and 128, and top plate 132. In various examples, a silicide layer (not shown) may be formed over contact regions 126 and 128 prior to forming contacts 140 thereon. Contacts 140 may each include (i) one or more metal-barrier and/or adhesion layers (e.g., titanium nitride (TiN), tantalum nitride (TaN), the like, or a combination thereof) conformally formed in a respective opening in first ILD layer 138 and (ii) a fill metal (e.g., aluminum (Al), copper (Cu), tungsten (W), the like, or a combination thereof) over and/or on the metal-barrier and/or adhesion layer(s).

First metal layer 142 is disposed over and on (and structurally connected to) contacts 140. In various examples, portions of first metal layer 142 disposed in die area 104 are further conductively connected to contacts 140, bottom plate contact 140a, and top plate contact 140b. In various examples, first metal layer 142 includes a plurality of metal lines, or portions. Each portion of first metal layer 142 may include one or more metal-barrier and/or adhesion layers (e.g., titanium nitride (TiN), tantalum nitride (TaN), the like, or a combination thereof) and a bulk metal (e.g., aluminum (Al), copper (Cu), the like, or a combination thereof) over and/or on the metal-barrier and/or adhesion layer(s).

Second ILD layer 144 is disposed over first metal layer 142 and first ILD layer 138. Second ILD layer 144 may include similar materials as first ILD layer 138. Vias 146 are disposed through second ILD layer 144 and on (and structurally connected to) first metal layer 142. Some of vias 146 in die area 104 are further electrically connected to the portions of first metal layer 142 in die area 104. Vias 146 may include similar materials as contacts 140. Second metal layer 148 is disposed over second ILD layer 144 and vias 146. Second metal layer 148 may include similar materials as first metal layer 142.

Third ILD layer 150 is disposed over second metal layer 148 and second ILD layer 144. Third ILD layer 150 may include similar materials as first ILD layer 138. Second metal layer 148 is disposed over second ILD layer 144 and vias 146. Additional ILD layers, vias, and metal layers may be formed over integrated circuit according to the desired design.

In various examples, portions of first metal layer 142, vias 146, and second metal layer 148 disposed in die area 104 may be part of an interconnect structure for integrated circuit 100. In other words, the portions of first metal layer 142, vias 146, and second metal layer 148 disposed in die area 104 may provide electrical connections to the various functional components of integrated circuit 100. In various examples, portions of first metal layer 142, vias 146, and second metal layer 148 disposed in scribe region 102 may be part of a dummy interconnect structure. In that regard, such a dummy interconnect structure, may prevent and/or reduce damage from occurring to die area 104 during a later performed semiconductor wafer dicing process.

Accordingly, decoupling capacitor 106 as disclosed herein may be disposed adjacent to and, in some examples, at least partially within scribe region 102. This allows decoupling capacitor 106 to occupy significantly less space within die area 104 than baseline processes. In that regard, deep well 118 (e.g., second portion 118b) disposed along the edge of scribe region 102 provides an electrical connection for the bottom plate (e.g., shallow well 122 ) of decoupling capacitor 106 to first buried layer 110 (e.g., second portion 110b). More specifically, the direct connection of shallow well 122 to deep well 118 along first length L₁ of decoupling capacitor 106 provides an electrical connection for decoupling capacitor 106 to a first voltage line (e.g., ground, substrate potential) through first buried layer 110. This electrical connection of shallow well 122 (e.g., bottom plate) to the first voltage line enables the top plate (e.g., top plate 132) of decoupling capacitor 106 to be formed of a continuous (e.g., non-interdigitated or non-finger like) material layer because there is no longer a need for openings to be formed through the top plate in order to provide a voltage connection to the bottom plate as in baseline processes. As such, decoupling capacitor 106 may be configured to extend significantly further along (e.g., length or y-direction) of scribe region 102 than into the die area 104 (e.g., width or x-direction) as compared to baseline processes. In various examples, the aspect ratio (ratio of length to width) may be in a range from about 20:1 to about 60:1, and in some examples from about 35:1 to about 45:1. This significantly reduces the space occupied by decoupling capacitor 106 within the die area 104 without negatively affecting the ESR of decoupling capacitor 106. Moreover, the absences of breaks (or openings) through top plate 132 reduces and/or prevents capacitive interference that may be caused breaks (or openings) in a top plate as used by baseline processes.

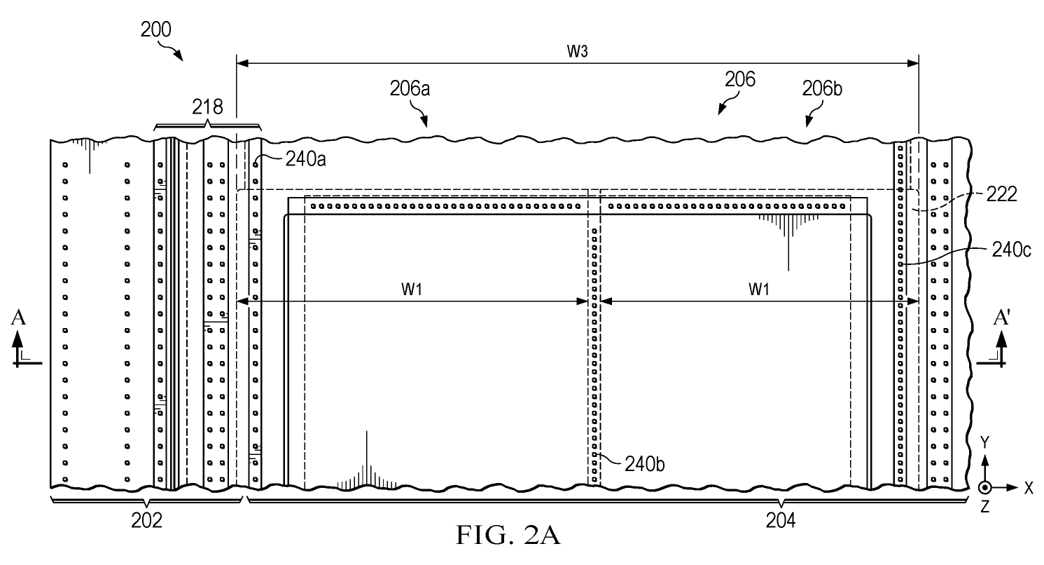

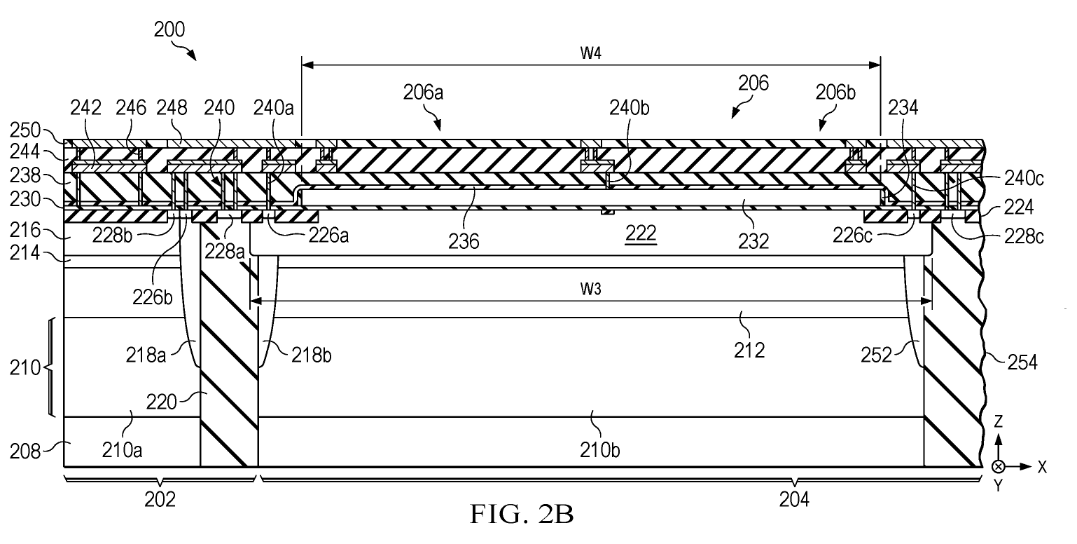

Referring now to FIGS. 2A and 2B, an integrated circuit 200 is shown according to various aspects of the present disclosure. FIG. 2A is a zoomed in top-down view of integrated circuit 200 and FIG. 2B is a diagrammatic cross-section view of integrated circuit 200 along the line A-A’ of FIG. 2A. Integrated circuit 200 includes similar components to integrated circuit 100 including a scribe region 202, a die area 204, a decoupling capacitor 206, a semiconductor substrate 208, a first buried layer 210 (including a first portion 210a and a second portion 210b), a semiconductor layer 212, a second buried layer 214, a doped semiconductor layer 216, a first deep well 218 (including a first portion 218a and a second portion 218b), a deep isolation structure 220, a shallow well 222, STI structures 224, contact regions 226a-226c, contact regions 228a-228c, a dielectric layer 230, a top plate 232, sidewall spacers 234, a dielectric liner 236, a first interlayer dielectric (ILD) layer 238, contacts 240 (including a first bottom plate contact 240a, a top plate contact 240b, and a second bottom plate contact 240c), a first metal layer 242, a second ILD layer 244, vias 246, a second metal layer 248, and a third ILD layer 250, descriptions of which will not be repeated below.

In that regard, decoupling capacitor 206 functions similar to decoupling capacitor 106 while being wider (e.g., along the x-axis) than decoupling capacitor 106. The greater width of decoupling capacitor 206 increases the effective capacitance without negatively affecting the equivalent series resistance (ESR) of decoupling capacitor 206. The effective capacitance is increased by increasing the width of both shallow well 222 (e.g., the bottom plate) and top plate 232. The ESR is maintained by providing an electrical connection between shallow well 222 and first buried layer 210 on both sides (e.g., the positive and negative x-directions) of shallow well 222 and providing an electrical connection to top plate 232 near the midline of top plate 232.

In that regard, decoupling capacitor 206 includes a first portion 206a and a second portion 206b. As shown, first portion 206a of decoupling capacitor 206 is delineated to the “left” (e.g., in the negative x-direction) of top plate contacts 240b and second portion 206b of decoupling capacitor 206 is delineated to the “right” (e.g., in the positive x-direction) of top plate contacts 240b. Similar to decoupling capacitor 106 of FIG. 1C, first portion 206a and second portion 206b of decoupling capacitor 206 include shallow well 222 forming a bottom plate, top plate 232 forming a top plate, and portion of dielectric layer 230 disposed between shallow well 222 and top plate 232 forming an insulator of the capacitor.

In some examples, first portion 206a and/or second portion 206b may be similar (e.g., size/dimensions and components) to decoupling capacitor 106. For example, first portion 206a and/or second portion 206b may extend first length L₁ (e.g., along an edge of scribe region 302 (e.g., along the y-axis)) similar to decoupling capacitor 106 as shown in FIG. 1A described above. Moreover, as shown in FIG. 1B, decoupling capacitor 206 has a third width W₃ that is about twice the size of first width W₁ (e.g., width W₁ of decoupling capacitor 106). For example, first portion 206a may have first W₁ and second portion 206b may have first width W₁, so that the total width of decoupling capacitor is third width W₃. Even though decoupling capacitor 206 has a greater overall width (e.g., third width W₃) than first capacitor 106 (e.g., first width W₁), first length L₁ may still be substantially greater than third width W₃. In various examples, a ratio of first length L₁ to third width W₃ (aspect ratio) may be about 10:1 to about 30:1, and in some examples about 15:1 to about 25:1 with respect to decoupling capacitor 206.

Integrated circuit 200 further includes a second deep well 252, a third isolation structure 254, contact region 226c, and contact region 228c. Second deep well 252 and third isolation structure 254 may be similar to first deep well 218 and deep isolation structure 220, respectively. Contact region 226c is disposed over shallow well 222 and second deep well 252 and is similar to contact regions 226a, 226b. Contact region 228c is disposed over third isolation structure 254 and is similar to contact regions 228a, 228b.

As shown, in various examples, shallow well 222 extends from deep isolation structure 220 to third isolation structure 254. Moreover, a first end of shallow well 222 (e.g., within first portion 206a) is disposed over portions of first deep well 218 (e.g., second portion 218b) and deep isolation structure 220 and an opposing second end of shallow well 222 (e.g., within second portion 206b) is disposed over portions of second deep well 252 and third isolation structure 254. As described below, an electrical connection between shallow well 222 and first buried layer 210 is formed on both sides (e.g., the positive and negative x-directions) of shallow well 222 through first deep well 218 and second deep well 252.

Decoupling capacitor 206 as shown in FIGS. 2A and 2B uses less space than baseline decoupling capacitors with little to no difference in ESR. Shallow well 222 (e.g., bottom plate) has two connections to a first voltage (e.g., ground) through first deep well 218 and second deep well 252 to first buried layer 210. Top plate 232 has a connection to a second voltage (e.g., VDD) through top plate contact 240b. As shown in FIG. 2B, top plate contact 240b may be disposed over and conductively coupled to top plate 232 at a point between deep isolation structure 220 and third isolation structure 254. In various examples, top plate contact 240b may be about equidistant from deep isolation structure 220 and third isolation structure 254. In other examples, top plate contacts 240b may be closer to one of deep isolation structure 220 or third isolation structure 254.

Accordingly, decoupling capacitor 206 as disclosed herein provides electrical connections to first buried layer 210 through shallow well 222, first deep well 218 and second deep well 252. Top plate 132 may then use one or more electrical connections along a midline of top plate 132 for first and second portions 206a and 206b of decoupling capacitor 206. Decoupling capacitor 206 may use less die space than baseline decoupling capacitors because there are no openings in top plate 232 to provide connections to shallow well 122. Furthermore, the architecture of decoupling capacitor 206 as disclosed herein ensures good electrical connection between shallow well 222 and first buried layer 210 with little to no effect on the ESR without introducing additional verification checks during manufacturing.

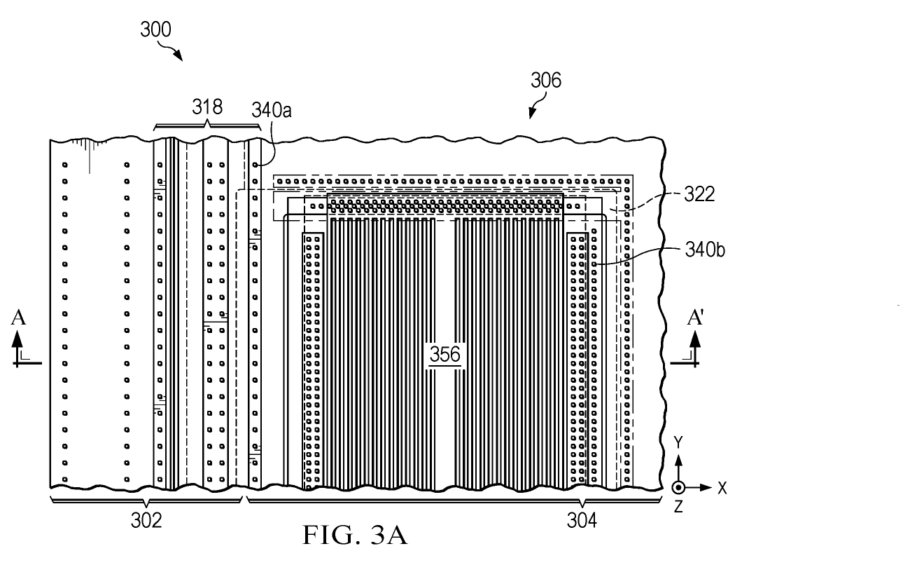

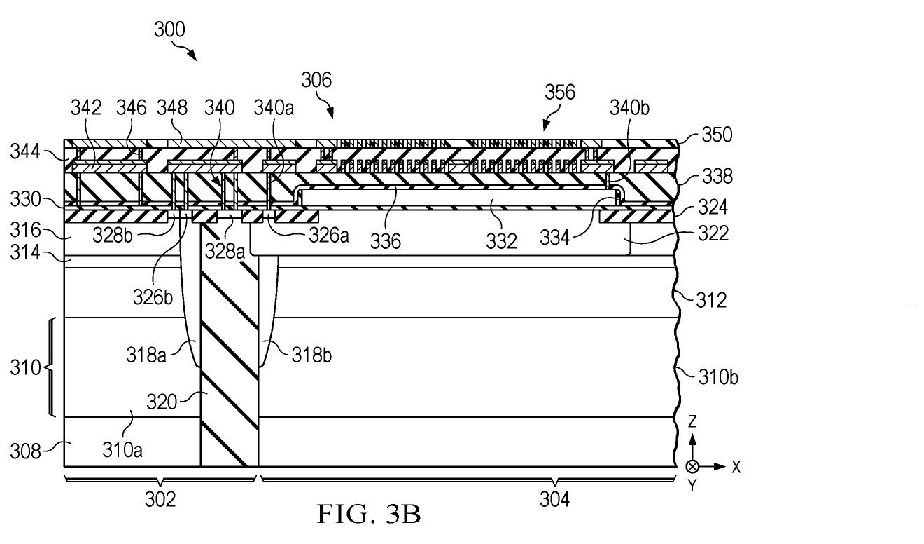

Referring now to FIGS. 3A and 3B, an integrated circuit 300 is shown according to various aspects of the present disclosure. FIG. 3A is a top-down view of integrated circuit 300 and FIG. 3B is a diagrammatic cross-section view of integrated circuit 300 along the line A-A’ of FIG. 3A. Integrated circuit 300 includes similar components to integrated circuit 100 including a scribe region 302, a die area 304, a decoupling capacitor 306, a semiconductor substrate 308, a first buried layer 310 (including a first portion 310a and a second portion 310b), a semiconductor layer 312, a second buried layer 314, a doped semiconductor layer 316, a deep well 318 (including a first portion 318a and a second portion 318b), a deep isolation structure 320, a shallow well 322, shallow isolation structures 324, contact regions 326a, 326b, contact regions 328a, 328b, a dielectric layer 330, a top plate 332, sidewall spacers 334, a dielectric liner 336, a first interlayer dielectric (ILD) layer 338, contacts 340 (including a bottom plate contact 340a and a top plate contact 340b), a first metal layer 342, a second ILD layer 344, vias 346, a second metal layer 348, and a third ILD layer 350, descriptions of which will not be repeated below.

Integrated circuit 300 further includes a metal-insulator-metal (MIM) capacitor 356 disposed over decoupling capacitor 306. MIM capacitor 356 may include portions of first metal layer 342, second ILD layer 344, and second metal layer 348. MIM capacitor 356 provides capacitance in parallel with decoupling capacitor 306 and increases the total capacitance available. In various examples, the total capacitance may be increased by about 5% to about 10% compared to baseline processes.

As described above, top plate 332 of decoupling capacitor 306 may be formed of a continuous (e.g., non-interdigitated or non-finger like) material layer because there is no longer a need for openings to be formed through the top plate in order to provide a voltage connection to the bottom plate, as in baseline processes. This is because of the direct connection of shallow well 322 (e.g., bottom plate) to deep well 318 (e.g., second portion 318b) provides an electrical connection for decoupling capacitor 306 to a first voltage line (e.g., ground, substrate potential) through first buried layer 310 (e.g., second portion 110b). As such, decoupling capacitor 306 may not have openings and/or contacts extending through top plate 332. This lack of openings and/or contacts provides additional space (e.g., room) for MIM capacitor 356 to be formed over decoupling capacitor 306. MIM capacitor 356 works in parallel with decoupling capacitor 306 to increase the overall capacitance while using less die space than baseline decoupling capacitors.

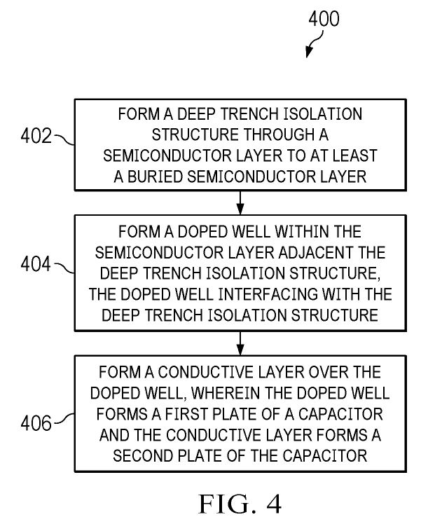

Referring now to FIG. 4, a flow diagram of a method 400 for forming a decoupling capacitor is shown, according to various examples of the present disclosure. At step 402, a deep trench isolation structure is formed through a semiconductor layer to at least a buried semiconductor layer. At step 404, a doped well is formed within the semiconductor layer adjacent the deep trench isolation structure, the doped well interfacing with the deep trench isolation structure. At step 406, a conductive layer is formed over the doped well, wherein the doped well forms a first plate of a capacitor and the conductive layer forms a second plate of the capacitor.

Disclosed herein are decoupling capacitors for integrated circuits that use less die space with little to no impact on ESR as compared to baseline decoupling capacitors. The decoupling capacitors disclosed herein are formed adjacent to and, in some examples, over the scribe region of an integrated circuit, providing a good connection to the substrate potential. The decoupling capacitor includes a bottom plate (e.g., a shallow well) that is formed over and directly contacting a deep well and an isolation structure. The deep well provides a good electrical connection to a buried semiconductor layer (e.g., substrate potential) for the bottom plate. The top plate of the capacitor is formed over the bottom plate as a single, continuous material without breaks. This combination reduces the die space used by the decoupling capacitor with little to no effect on the ESR of the decoupling capacitor. In various examples, multiple decoupling capacitors may be disposed adjacent each other. In various examples, a MIM capacitor may be formed over the decoupling capacitor to increase the overall capacitance.

Finally, it should be understood that any of the above-described concepts can be used alone or in combination with any or all of the other above-described concepts. Although various examples have been disclosed and described, it is understood, recognized, and/or contemplated that certain modifications would come within the scope of this disclosure. Accordingly, the description is not intended to be exhaustive or to limit the principles described or illustrated herein to any precise form. Many modifications and variations are possible in light of the above teaching.

What is claimed is:

1. An integrated circuit, comprising:
a buried semiconductor layer disposed over a substrate and having a first conductivity type;
an epitaxial layer disposed over the buried semiconductor layer and having an opposite second conductivity type;
a deep trench isolation structure extending through the epitaxial layer, the buried semiconductor layer and into the substrate; and
a capacitor disposed over the substrate, the capacitor interfacing with the deep trench isolation structure and electrically coupled to the buried semiconductor layer.

2. The integrated circuit of claim 1, wherein the capacitor includes a first plate electrically coupled to the buried semiconductor layer and interfacing with the deep trench isolation structure.

3. The integrated circuit of claim 2, further comprising:
a first doped region disposed within the epitaxial layer along a sidewall of the deep trench isolation structure, the first doped region extending from the first plate of the capacitor to the buried semiconductor layer.

4. The integrated circuit of claim 3, further comprising:
a second doped region disposed within the epitaxial layer adjacent the first doped region, the first doped region having the first conductivity type and the second doped region having the second conductivity type.

5. The integrated circuit of claim 2, wherein the capacitor further includes a second plate that is conductively isolated from the buried semiconductor layer and is spaced apart from the deep trench isolation structure laterally with respect to a top surface of the first plate.

6. The integrated circuit of claim 5, wherein the first plate has a different material composition than the second plate.

7. The integrated circuit of claim 5, wherein the first plate of the capacitor includes a shallow doped well disposed within the epitaxial layer and the second plate of the capacitor includes a polysilicon structure disposed over the first plate.

8. The integrated circuit of claim 1, wherein the deep trench isolation structure is disposed within a scribe region of the substrate.

9. The integrated circuit of claim 1, wherein the buried semiconductor layer is
an n-type buried semiconductor layer, and
wherein the capacitor includes an n-type doped well
forming a plate of the capacitor, the n-type doped well
disposed within the epitaxial layer and conductively
coupled to the n-type buried semiconductor layer.

10. The integrated circuit of claim 1, wherein the capacitor includes a first doped feature forming a plate of the capacitor, the first doped feature conductively coupled to the buried semiconductor layer and having the first conductivity type, the integrated circuit further comprising:
a second doped feature at least partially surrounded by the first doped feature and having a higher conductivity than the first doped feature; and
a contact electrically coupled to the second doped feature.

11. The integrated circuit of claim 1, wherein the capacitor has a length and a width, wherein a ratio of the length to the width is in a range from about 20:1 to about 40:1.

12. The integrated circuit of claim 1, wherein the deep trench isolation structure is a first deep trench isolation structure, and further comprising:
a second deep trench isolation structure disposed over the substrate and extending through the buried semiconductor layer, wherein a plate of the capacitor extends from the first deep trench isolation structure to the second deep trench isolation structure.

13. An electronic device, comprising:
a buried semiconductor layer having a first conductivity type disposed over a semiconductor substrate;
a semiconductor layer having an opposite second conductivity type disposed over the buried semiconductor layer;
a trench extending through the semiconductor layer to at least the buried semiconductor layer;
a doped region disposed within the semiconductor layer along a sidewall of the trench, the doped region extending to at least the buried semiconductor layer and having the first conductivity type; and
a capacitor, the capacitor including a doped well forming a plate of the capacitor, the doped well disposed within the semiconductor layer and having the first conductivity type, the doped well interfacing with the trench and the doped region, wherein the doped well is conductively coupled to the buried semiconductor layer by the doped region.

14. The electronic device of claim 13, wherein the doped well is a first plate of the capacitor, and wherein the capacitor further includes:
a polysilicon layer forming a second plate of the capacitor, the polysilicon layer disposed over the doped well;
a dielectric layer disposed between the doped well and the polysilicon layer, the device further comprising:
a first contact disposed through the dielectric layer and conductively coupled to the doped well; and
a second contact conductively coupled to the polysilicon layer.

15. The electronic device of claim 14, wherein the trench is disposed within a scribe region of the semiconductor substrate.

16. The electronic device of claim 14, the device further comprising:
a first metal layer including a plurality of metal lines disposed over the polysilicon layer and electrically coupled to the first contact and the second contact; and
a second metal layer including a plurality of metal lines disposed over the first metal layer.

17. The electronic device of claim 16, wherein the capacitor is a first capacitor and wherein the plurality of metal lines form a second capacitor electrically connected in parallel with the first capacitor.

18. A method of forming an integrated circuit, comprising:
forming a trench through a first semiconductor layer having a first conductivity type to a second semiconductor layer having an opposite second conductivity type;
forming a doped region having the second conductivity type within the first semiconductor layer, the doped region intersecting a sidewall of the trench; and
forming a conductive layer over the doped region, wherein the doped region forms a first plate of a capacitor and the conductive layer forms a second plate of the capacitor.

19. The method of claim 18, further comprising forming a doped region in the first semiconductor layer and the second semiconductor layer, wherein the doped region is conductively coupled to the second semiconductor layer by the doped region.

20. The method of claim 18, wherein forming the trench through the first semiconductor layer includes forming a material layer through the first semiconductor layer, the material layer including a dielectric material or a conductive material.
